(19) United States
(12) Patent Application Publication
(10) Pub. No.: US 2011/0049554 A1
(43) Pub. Date: Mar. 3, 2011

(54) PACKAGE BASE STRUCTURE AND MANUFACTURING METHOD THEREOF

(75) Inventors: Mao-Jen Wu, Taoyuan (TW); Hsiao-Chin Lan, Taoyuan (TW); An-Nong Wen, Taoyuan (TW); Chih-Hung Hsu, Taoyuan (TW); Hsu-Liang Hsiao, Taoyuan (TW); Chia-Chi Chang, Taoyuan (TW); Chia-Yu Lee, Taoyuan (TW); Siou-Ping Chen, Taoyuan (TW); Min-Hao Chung, Taoyuan (TW)

(73) Assignee: NATIONAL CENTRAL UNIVERSITY, Taoyuan (TW)

(21) Appl. No.: 12/870,061

(22) Filed: Aug. 27, 2010

(30) Foreign Application Priority Data
Aug. 27, 2009 (TW) 098128865

(51) Int. Cl. H01L 33/48; H01L 21/3065

(52) U.S. Cl. 257/98; 438/704; 257/E21.218; 257/E33.056

(57) ABSTRACT

A package base structure for packaging a light-emitting element and a related manufacturing process are provided. The package base structure includes a semiconductor substrate having a top surface, a receiving space in the top surface and defined by slant surfaces, and a micro diffractive optical element on one of the slant surfaces. To produce the package base structure, a first etching mask with a first etching window is formed on the top surface. The etching window has a sidewall oriented at a bias angle with respect to a specific equivalent crystallographic orientation of the semiconductor substrate. Then, a selective anisotropic etching procedure is performed through the first etching window to form the slant surfaces on the semiconductor substrate. Afterwards, the micro diffractive optical element is formed on the slant surface for collimating or focusing a light beam emitted from the light-emitting element.

### FIELD OF THE INVENTION

The present invention relates to a package base structure, and more particularly to a package base structure for packaging a light emitting diode. The present invention also relates to a method of manufacturing such a package base structure.

### BACKGROUND OF THE INVENTION

For most optoelectronic systems, the mechanism for changing the optical path is very important. FIG. 1 is a schematic perspective view illustrating a package base structure according to the prior art. The package base structure has a reflective surface 120 for deflecting the light emitted by the light-emitting element 11 to the out-of-plane direction with respect to the substrate 10. As shown in FIG. 1, a glass block 12 having a 45-degree reflective surface 120 is bonded on a substrate 10. In addition, a micro lens 13 is mounted on the upper edge of the 45-degree reflective surface 120. As such, the light beam emitted by the light-emitting element 11 is reflected by the reflective surface 120 and then focused and collimated by the micro lens 13. The conventional package base structure, however, still has some drawbacks. For example, since the light-emitting element 11, the glass block 12 and the micro lens 13 are discrete elements, the package base structure is very costly. Since the light-emitting element 11, the glass block 12 and the micro lens 13 need to be precisely aligned with each other, the process of manufacturing the package base structure is not cost-effective, and the mass production of the package base structure is difficult.

Therefore, there is a need of providing a package base structure and a manufacturing method thereof in order to obviate the drawbacks encountered from the prior art.

### SUMMARY OF THE INVENTION

In accordance with an aspect of the present invention, there is provided a manufacturing process of a package base structure. Firstly, a semiconductor substrate having a top surface is provided. Then, a first etching mask with a first etching window is formed on the top surface of the semiconductor substrate. The etching window has a sidewall oriented at a bias angle with respect to a specific equivalent crystallographic orientation of the semiconductor substrate. The bias angle ranges from 0 degree to 90 degrees except 45 degrees. Then, a selective anisotropic etching procedure is performed through the first etching window to form a slant surface on the semiconductor substrate. Then, a second etching mask with a plurality of second etching windows is formed on the slant surface. Afterwards, an etching process is performed through the second etching windows to form a micro diffractive optical element with a plurality of trenches on the slant surface.

In accordance with another aspect of the present invention, there is provided a package base structure for packaging a light-emitting element. The package base structure includes a semiconductor substrate, a receiving space and a micro diffractive optical element. The semiconductor substrate has a top surface. The receiving space is disposed in the tope surface of the semiconductor substrate and defined by a plurality of slant surfaces. A specified slant surface of the plurality of slant surfaces is oriented at a bias angle with respect to a specific equivalent crystallographic orientation of the semiconductor substrate. The bias angle ranges from 0 degree to 90 degrees except 45 degrees. The micro diffractive optical element is formed on the specified slant surface and having a plurality of trenches for collimating or focusing a light beam that is emitted by the light-emitting element.

### BRIEF DESCRIPTION OF THE DRAWINGS

The above contents of the present invention will become more readily apparent to those ordinarily skilled in the art after reviewing the following detailed description and accompanying drawings, in which:

FIG. 1 is a schematic perspective view illustrating a package base structure according to the prior art;

FIG. 2A is a schematic top perspective view illustrating a package base structure according to an embodiment of the present invention;

FIG. 2B is a cross-sectional view illustrating the package base structure of FIG. 2A taken along line D-D′;

FIG. 2C is a cross-sectional view illustrating the package base structure of FIG. 2A taken along line E-E′;

FIGS. 3A˜3J are schematic cross-sectional views illustrating a process for manufacturing a package base structure according to the present invention;

FIG. 4 is a schematic perspective view illustrating an exemplary micro diffractive optical element of the package base structure according to an embodiment of the present invention; and

FIG. 5 is a schematic perspective view illustrating another exemplary micro diffractive optical element of the package base structure according to an embodiment of the present invention.

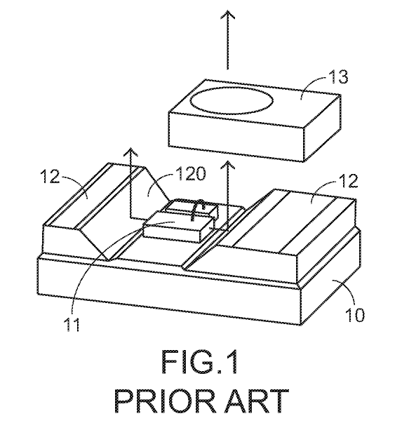

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

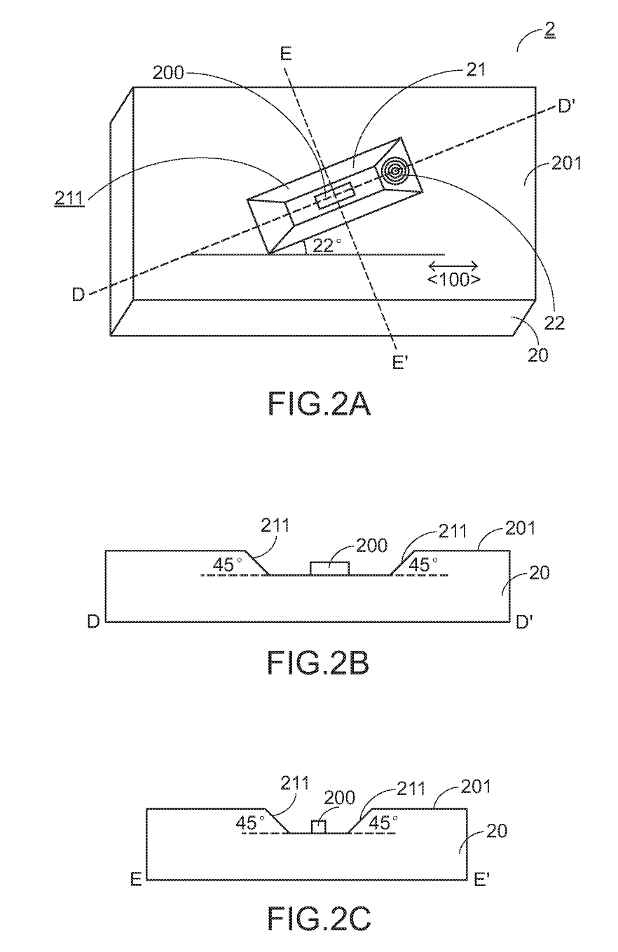

FIG. 2A is a schematic top perspective view illustrating a package base structure according to an embodiment of the present invention. FIG. 2B is a cross-sectional view illustrating the package base structure of FIG. 2A taken along line D-D′. FIG. 2C is a cross-sectional view illustrating the package base structure of FIG. 2A taken along line E-E′. Please refer to FIGS. 2A, 2B and 2C. The package base structure 2 is used for packaging a semiconducting light-emitting element 200. An example of the semiconducting light-emitting element 200 includes but is not limited to an optical pickup head of an optical storage device, a light emitting diode (LED) or a laser diode for use in edge-emitting laser or vertical-cavity surface-emitting laser.

As shown in FIG. 2A, the package base structure 2 comprises a semiconductor substrate 20, a receiving space 21 and a micro diffractive optical element 22. The semiconductor substrate 20 is a silicon substrate with a diamond crystalline structure. The semiconductor substrate 20 has a top surface 201, which is a {100} equivalent crystallographic surface. The receiving space 21 is defined by a plurality of slant surfaces 211. These slant surfaces 211 are extended in the direction D-D′ and the direction E-E′, respectively. The slant surface 211 in the direction D-D′ is oriented at a bias angle α with respect to the <100> equivalent crystallographic orientation of the semiconductor substrate 20. The bias angle α is greater than or equal to 0 degree and smaller than 45 degrees, or greater than 45 degrees and smaller than or equal to 90 degrees. For obtaining an optimum effect, the bias angle is 22 degrees in this embodiment.

As shown in FIG. 2B, the slant surface 211 is on a {110} equivalent crystallographic plane of the semiconductor substrate 20. In addition, the slant surface 211 is a 45-degree slant surface with respect to the {100} equivalent crystallographic surface 201. As shown in FIG. 2B, the slant surface 211 is also on the {110} equivalent crystallographic plane of the semiconductor substrate 20. In addition, the slant surface 211 is a 45-degree slant surface with respect to the {100} equivalent crystallographic surface 201. In accordance with a key feature of the present invention, the micro diffractive optical element 22 is formed on the slant surface 211 in the direction D-D′. When the light beam emitted by the light-emitting element 200 is projected on the micro diffractive optical element 22 formed on the slant surface 211, the light beam will be successfully deflected to the out-of-plane direction. In addition, the light beam could be collimated or focused by the micro diffractive optical element 22. The monolithic package base structure 2 of the present invention has the functions of deflecting the light beam to the out-of-plane direction and collimating or focusing the light beam.

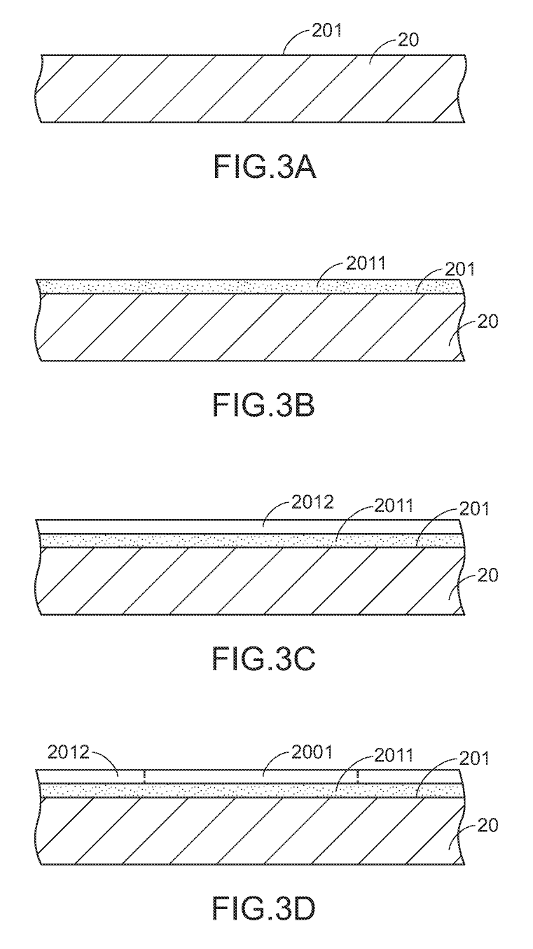

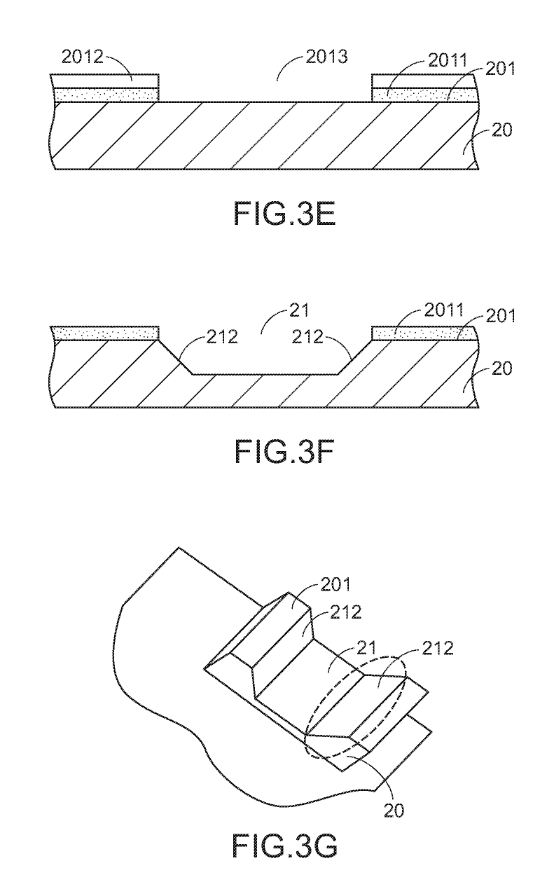

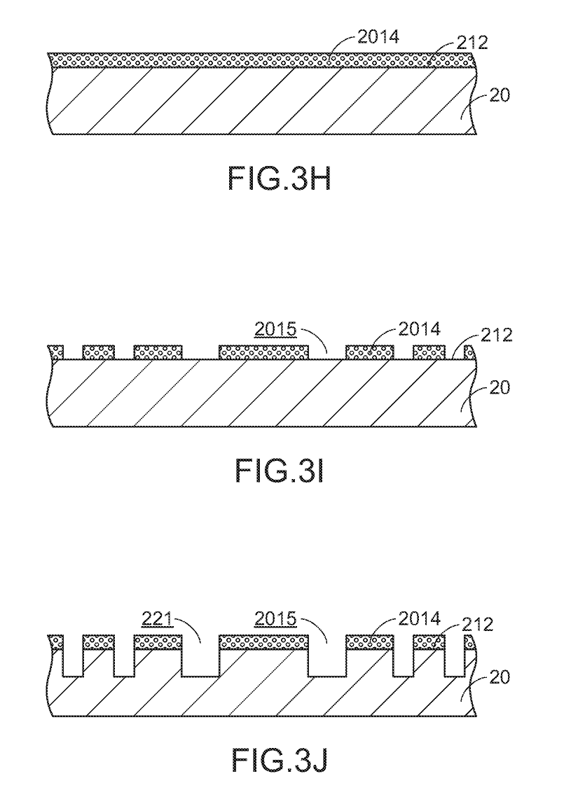

FIGS. 3A˜3J are schematic cross-sectional views illustrating a process for manufacturing a package base structure according to the present invention. The process for manufacturing the package base structure is applied to a semiconductor fabricating process. Firstly, as shown in FIG. 3A, a semiconductor substrate 20 having a {100} equivalent crystallographic top surface 201 is provided. Then, as shown in FIG. 3B, a mask layer 2011 made of silicon nitride is formed on the top surface 201 of the semiconductor substrate 20. Then, as shown in FIG. 3C, a photoresist layer 2012 is formed on the mask layer 2011. Then, as shown in FIG. 3D, a photoresist pattern 2001 is defined in the photoresist layer 2012 by means of a photomask (not shown). Then, according to the photoresist pattern 2001, the mask layer 2011 is etched by a reactive ion etching (RIE) process to form an etching window 2013 (see FIG. 3E). As shown in FIG. 3F, the photoresist pattern 2001 is removed, and then a wet etching process is performed to partially etch off the semiconductor substrate 20 through the etching window 2013, thereby forming a receiving space 21 defined by a plurality of slant surfaces 212. In this embodiment, the wet etching process is a selective anisotropic etching procedure. The etchant solution used in the selective anisotropic etching procedure can be a mixture of potassium hydroxide, water and isopropanol. The proportions of the components in the mixture depend on the desired etching rate. The temperature of the etchant solution ranges from 60° C. to 95° C. during the selective anisotropic etching procedure. In addition, during the selective anisotropic etching procedure, the etchant solution should be continuously stirred to remove bubbles, which are possibly adhered onto the slant surfaces to adversely affect the surface smoothness.

After the residual mask layer 2011 is removed (see FIG. 3G), an e-beam writing process is performed on one of the plurality of slant surfaces 212. By the way, the slant surface 212 (i.e. the reflective surface) needs to be perpendicular to the electron beam before the E-beam writing process is performed. As shown in FIG. 3G, the semiconductor substrate 20 is tilted at a tilt angle such that the slant surface 212 is perpendicular to the electron beam. Then, as shown in FIG. 3H, a mask layer 2014 is formed on the slant surface 212 (i.e. the reflective surface). For clarification, only the circled portion of FIG. 3G is shown in FIGS. 3H˜3J. Then, as shown in FIG. 3H, the mask layer 2014 is etched by an E-beam writing process to form a plurality of etching windows 2015. Then, as shown in FIG. 3J, a reactive ion etching (RIE) process is performed to partially etch off the semiconductor substrate 20 through the etching windows 2015, thereby forming a micro diffractive optical element 22 with a plurality of trenches 221 on the slant surface 212. Afterwards, the remaining mask layer 2014 is removed. The resulted package base structure 2 is shown in FIGS. 2A, 2B and 2C.

In the embodiment of the present invention, the semiconductor substrate 20 having the {100} equivalent crystallographic top surface 201 is provided. Generally, the {111} equivalent crystallographic surface is more stable. The bias angle of 45 degrees is not suitable because a great amount of {111} equivalent crystallographic micro-planes are possibly induced. In this situation, the surface smoothness of the slant surface 212 (i.e. the reflective surface) is deteriorated. It is found that the bias angle close to 0 degree or 90 degrees will result in a better surface smoothness of the slant surface 212 (i.e. the reflective surface), but the deviation of the formed slant surface 212 from the perfect 45-degree slant surface is increased. On the other hand, if the bias angle is close to 45 degrees, the deviation of the formed slant surface 212 from the perfect 45-degree slant surface is decreased, but the surface smoothness of the slant surface 212 (i.e. the reflective surface) is impaired. The selection is up to the manufacturer depending on practical requirements. For example, when it is required to obtain a 45-degree angle between the top surface 201 of the semiconductor substrate 20 and the slant surface 212 with an acceptable deviation ±1 degree, the bias angle should be controlled in the range between 22 degrees to 68 degrees except 45 degrees.

In the foregoing, the present invention is illustrated by referring to the semiconductor substrate 20 having a {100} equivalent crystallographic surface 201. Nevertheless, the present invention can also be applied to a semiconductor substrate having a {110} equivalent crystallographic surface or <110> equivalent crystallographic orientation. Thus, the plurality of slant surfaces produced by the selective anisotropic etching procedure are on the {100} equivalent crystallographic plane.

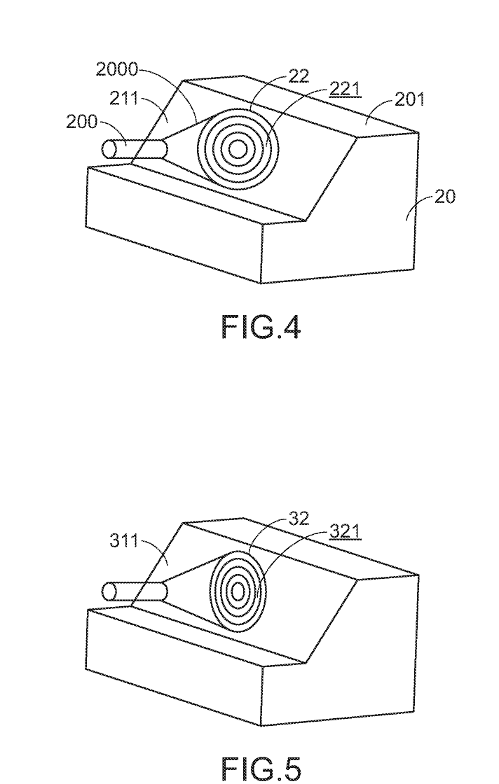

FIG. 4 is a schematic perspective view illustrating an exemplary micro diffractive optical element of the package base structure according to an embodiment of the present invention. As shown in FIG. 4, the micro diffractive optical element 22 has a circular profile. In addition, the micro diffractive optical element 22 comprises a plurality of trenches 221. When the light beam 2000 emitted by the light-emitting element 200 is projected on the slant surface 211 of the micro diffractive optical element 22, the light beam 2000 will be successfully deflected to the out-of-plane direction. In addition, the light beam 2000 could be collimated or focused by the micro diffractive optical element 22.

FIG. 5 is a schematic perspective view illustrating another exemplary micro diffractive optical element of the package base structure according to an embodiment of the present invention. As shown in FIG. 5, the micro diffractive optical element 32 has an elliptical profile. Since the micro diffractive optical element makes the light beam deflect by a large angle, serious off-axis aberration (e.g. astigmatic aberration) will be resulted from different refraction power in the sagittal-plane direction and the tangential-plane direction. The elliptical profile of the micro diffractive optical element 32 could provide different refraction power in two dimensions in order to correct off-axis aberration of the 45-degree slant surface 311 (i.e. the reflective surface).

From the above discussion, it is fount that the micro diffractive optical element has a function of the general reflective concave mirror. A radius of curvature and an aspheric coefficient of the concave mirror are important parameters for determining focal length, aberration control and tolerance. After the parameters of the concave mirror are decided, equiphase surfaces of the concave mirror are defined according to the wavelength. The neighboring equiphase surface has an optical path difference for a single wavelength. After the equiphase surfaces corresponding to the integer part are eliminated, the micro diffractive optical element 22 or 32 perfectly equivalent to the concave mirror is obtained. The distance between the adjacent trenches 221 or 321 of the micro diffractive optical element 22 or 32 (see FIGS. 4 and 5) is varied according to the wavelength and the optical imaging design.

It is noted that the micro diffractive optical elements used in the package base structure of FIGS. 4 and 5 may be modified while retaining the teachings of the invention. For example, other micro diffractive optical element such as an optical grating could be used to split and diffract light.

In the above embodiments, the micro diffractive optical element is formed on the slant surface by a reactive ion etching (RIE) process. It is noted that, however, those skilled in the art will readily observe that numerous modifications and alterations may be made while retaining the teachings of the invention. For example, in some embodiments, the micro diffractive optical element is firstly formed on a plastic polymeric film, and then the micro diffractive optical element is attached on the slant surface of the semiconductor substrate by a hybrid integration process. In this situation, the package base structure still has the functions of deflecting the light beam to the out-of-plane direction and collimating or focusing the light beam.

As previously described, since the light-emitting element, the glass block and the micro lens of the conventional package base structure are discrete elements, the conventional process of manufacturing the package base structure is costly and fails to be mass produced. From the above description, the package base structure of the present invention has the functions of deflecting the light beam to the out-of-plane direction and collimating or focusing the light beam by means of monolithic integration. In other words, the process for manufacturing the package base structure is very cost-effective and the mass production of the package base structure is feasible.

While the invention has been described in terms of what is presently considered to be the most practical and preferred embodiments, it is to be understood that the invention needs not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A manufacturing process of a package base structure, the manufacturing process comprising steps of:
providing a semiconductor substrate having a top surface;
forming a first etching mask with a first etching window on the top surface of the semiconductor substrate, the etching window having a sidewall oriented at a bias angle with respect to a specific equivalent crystallographic orientation of the semiconductor substrate, wherein the bias angle ranges from 0 degree to 90 degrees except 45 degrees;
performing a selective anisotropic etching procedure through the first etching window to form a slant surface on the semiconductor substrate;
forming a second etching mask with a plurality of second etching windows on the slant surface; and
performing an etching process through the second etching windows to form a micro diffractive optical element with a plurality of trenches on the slant surface.

2. The manufacturing process according to claim 1 wherein the top surface of the semiconductor substrate is a {100} equivalent crystallographic surface, the sidewall is oriented at the bias angle with respect to a <100> equivalent crystallographic orientation of the semiconductor substrate, and the slant surface is on a {110} equivalent crystallographic plane.

3. The manufacturing process according to claim 1 wherein the top surface of the semiconductor substrate is a {110} equivalent crystallographic surface, the sidewall is oriented at the bias angle with respect to a <110> equivalent crystallographic orientation of the semiconductor substrate, and the slant surface is on a {100} equivalent crystallographic plane.

4. The manufacturing process according to claim 1 wherein the semiconductor substrate is a silicon substrate with a diamond crystalline structure.

5. The manufacturing process according to claim 1 wherein the selective anisotropic etching procedure is a wet etching procedure carried out in an etchant solution, and the etchant solution is a mixture of potassium hydroxide, water and isopropanol.

6. The manufacturing process according to claim 1 wherein the bias angle ranges from 22 degrees to 68 degrees except 45 degrees.

7. The manufacturing process according to claim 1 wherein the selective anisotropic etching procedure is performed at a temperature of said etchant solution ranging from 60° C. to 95° C. with stirring.

8. The manufacturing process according to claim 1 wherein the first etching window of the first etching mask is produced by steps of:
forming a photoresist layer on the first mask layer;
defining a photoresist pattern on the photoresist layer by a photomask; and
performing a reactive ion etching (RIE) process to form the first etching window on the first mask layer according to the photoresist pattern.

9. The manufacturing process according to claim 1 wherein the plurality of second etching windows of the second etching mask are produced by an e-beam writing process.

10. The manufacturing process according to claim 1 wherein the micro diffractive optical element is formed on the slant surface by a reactive ion etching (RIE) process.

11. A manufacturing process of a package base structure, the manufacturing process comprising steps of:
providing a semiconductor substrate having a top surface;
forming a first etching mask with a first etching window on the top surface of the semiconductor substrate, the etching window having a sidewall oriented at a bias angle with respect to a specific equivalent crystallographic orientation of the semiconductor substrate, wherein the bias angle ranges from 0 degree to 90 degrees except 45 degrees;
performing a selective anisotropic etching procedure through the first etching window to form a slant surface on the semiconductor substrate;
forming a micro diffractive optical element on a plastic polymeric film; and
attaching the micro diffractive optical element on the slant surface by a hybrid integration process.

12. A package base structure for packaging a light-emitting element, the package base structure comprising:
a semiconductor substrate having a top surface;
a receiving space disposed in the top surface of the semiconductor substrate and defined by a plurality of slant surfaces, wherein a specified slant surface of the plurality of slant surfaces is oriented at a bias angle with respect to a specific equivalent crystallographic orientation of the semiconductor substrate, wherein the bias angle ranges from 0 degree to 90 degrees except 45 degrees; and
a micro diffractive optical element formed on the specified slant surface for collimating or focusing a light beam that is emitted by the light-emitting element.

13. The package base structure according to claim 12 wherein the semiconductor substrate is a silicon substrate with a diamond crystalline structure.

14. The package base structure according to claim 12 wherein the top surface of the semiconductor substrate is a {100} equivalent crystallographic surface, and the specified slant surface is on a {110} equivalent crystallographic plane.

15. The package base structure according to claim 12 wherein the top surface of the semiconductor substrate is a {110} equivalent crystallographic surface, and the specified slant surface is on a {100} equivalent crystallographic plane.

16. The package base structure according to claim 12 wherein an angle between the specified slant surface and the top surface of the semiconductor substrate is equal to 45 degrees.

17. The package base structure according to claim 12 wherein the micro diffractive optical element has a plurality of trenches with a circular profile or an elliptical profile.

18. The package base structure according to claim 12 wherein the micro diffractive optical element is a grating.

19. The package base structure according to claim 12 wherein the micro diffractive optical element has a function of a concave mirror.

20. The package base structure according to claim 12 wherein the light-emitting element is an optical pickup head, a light emitting diode, or a laser diode of an edge-emitting laser or a vertical-cavity surface-emitting laser.
